(19) United States
(12) Patent Application Publication
(10) Pub. No.: US 2026/0115566 A1
(43) Pub. Date: Apr. 30, 2026

(54) PRESSURE-SENSITIVE STACKING STRUCTURE FOR SPORTS TRAINING DEVICE, METHOD FOR MANUFACTURING THE SAME, AND GOLF PRACTICE DEVICE INCLUDING THE SAME

(71) Applicant: SGLAB INC., Ansan-si (KR)

(72) Inventors: Eddie CHO, Seoul (KR); Taeeun KIM, Seogwipo-si (KR); Jichang HWANG, Seoul (KR)

(73) Assignee: SGLAB INC., Ansan-si (KR)

(21) Appl. No.: 19/167,929

(22) PCT Filed: Oct. 28, 2024
(86) PCT No.: PCT/KR2024/016498

§ 371 Date: Sep. 23, 2025

(30) Foreign Application Priority Data
Oct. 25, 2024 (KR) 10-2024-0147907

(51) Int. Cl. A63B 69/36; G01L 1/20; H05K 3/28

(52) U.S. Cl. CPC A63B 69/3632; H05K 3/28; G01L 1/20

(57) ABSTRACT

A pressure-sensitive stacking structure for a sports training device of the present invention that is able to detect a pressure with which a player grips a grip portion may include: a conductive layer that is pressure-sensitive; a circuit layer disposed to face the conductive layer and having a plurality of conductive patterns; and a separating layer disposed between the conductive layer and the circuit layer and formed of a fibrous tissue including a plurality of fibers, wherein, when a pressure is generated, the conductive layer and the circuit layer may come into contact, and the pressure may be detected.

### TECHNICAL FIELD

The present invention relates to a pressure-sensitive stacking structure for a sports training device, a method for manufacturing the same, and a golf practice device including the same, and more particularly, to a pressure-sensitive stacking structure for a sports training device that can assist in sports training by measuring a pressure with which a user grips a sports tool, a method for manufacturing the same, and a golf practice device including the same.

### BACKGROUND ART

Among various sports, unique tools are used in some sports. In particular, in sports such as baseball and golf, a player uses a baseball bat or a golf club.

Among the sports in which sports tools are used, golf is a sport in which a golf ball is hit into holes on a golf course. Accordingly, a golfer should hit a golf ball by swinging a golf club to hit the golf ball into holes, and a lot of practice is necessary for the golfer to play with a small number of strokes.

Meanwhile, holding a grip of a golf club with both hands is the start of a swing. In particular, an appropriate grip strength is a prerequisite for a smooth swing, and if the grip is held too tight, the whole body may stiffen and cause a mishit. However, many golfers unintentionally hold the grip too tight. In reality, it has been found out that there is a huge difference in a grip holding strength, that is, grip strength, between professional golfers and amateur golfers.

Accordingly, golf trainers advise golfers to always “relax the grip and hit” in order to achieve a consistent golf swing. However, it is difficult for golf beginners to relax the grip and hit during a golf swing.

Golf Magazine, an American golf magazine, has released a computer analysis of a change in grip strength during a swing of professional golfers and amateur golfers. As a result, experimental results showed that amateur golfers hold the grip with twice as much strength than professional golfers.

An appropriate grip strength is one reason for a smooth swing of professional golfers. First, grip strength at the time of address was found to be similar between professional golfers (20%) and amateur golfers (26%). However, study results showed that, upon the start of a backswing, while the grip strength of the professional golfers insignificantly increased to 29%, the grip strength of the amateur golfers significantly increased to 52%.

Even at the top of the backswing, while the grip strength of the professional golfers increased by about two times that at the time of address to 48%, the grip strength of the amateur golfers drastically increased to 78%, which was three times that at the time of address. This is due to lifting a golf club only with arms while the torso is not sufficiently rotated. This is being pointed out as a cause of an outside-in swing trajectory that leads to a slice or a hook. At impact, the grip strength of the professional golfers was 85%, the grip strength of the amateur golfers was 97%, and there was no great difference between them. However, at a follow through around the waist after impact, while the grip strength of the professional golfers was 25%, the grip strength of the amateur golfers was 55%, which was more than two times that of the professional golfers. That is, while the professional players increase the grip strength only at necessary moments, the grip strength of the amateur players is always high. In particular, an angle formed between the left arm and the shaft of a club upon the start of a downswing from the top of the backswing was 104° in the professional players but only 75° in the amateur players. This is one reason why strokes of professional players are longer. The angle of the professional players can accelerate a club head speed until impact.

A method recommended by trainers to prevent stiffening of the body due to strong grip is to practice light grip in which the left hand holds the grip as per usual and the right hand is put next to the left hand. Development of golf tools for such a practicing method is necessary, and such golf tools may be good for correcting existing swing habits of amateur golfers.

Accordingly, there is a need for development of a member for pressure measurement that can measure and digitize a grip pressure of a golfer.

The inventor of the present invention has conducted research for a long period of time to meet the demand for development of the golf practice device described above and has completed the present invention after trial and error.

### DISCLOSURE

### Technical Problem

The present invention has been devised to address the problems of the related art, and one objective of the present invention is to provide a pressure-sensitive stacking structure for a sports training device that can assist in golf practice by measuring a pressure with which a golfer holds a grip of a golf club, a method for manufacturing the same, and a golf practice device including the same.

Meanwhile, other unmentioned objectives of the present invention will be additionally taken into consideration within the scope easily inferable from the following detailed description and advantageous effects thereof.

### Technical Solution

One aspect of the present invention provides a pressure-sensitive stacking structure for a sports training device that is able to detect a pressure with which a player grips a grip portion, the pressure-sensitive stacking structure including: a conductive layer that is pressure-sensitive; a circuit layer disposed to face the conductive layer and having a plurality of conductive patterns; and a separating layer disposed between the conductive layer and the circuit layer and formed of a fibrous tissue including a plurality of fibers, wherein, when a pressure is generated, the conductive layer and the circuit layer may come into contact, and the pressure may be detected.

In one embodiment of the present invention, the separating layer may have restorability and may separate the conductive layer and the circuit layer.

In one embodiment of the present invention, a thickness of the separating layer may range from 0.01 mm to 0.02 mm.

In one embodiment of the present invention, the separating layer may be formed using at least one selected from the group consisting of polydimethylsiloxane (PDMS), thermoplastic polyurethane (TPU), and epoxy.

In one embodiment of the present invention, the separating layer may be formed by performing one of a spin coating method, an electrospinning method, and a roll-to-roll method on the at least one selected from the group.

In one embodiment of the present invention, the separating layer may be formed by electrospinning TPU or epoxy.

In one embodiment of the present invention, the conductive layer may have resistance changing according to pressure and may have resilience.

In one embodiment of the present invention, the resistance of the conductive layer may decrease due to the pressure.

In one embodiment of the present invention, the circuit layer may be made of a flexible printed circuit board (FPCB) including a plurality of pattern areas including the plurality of conductive patterns, and the plurality of pattern areas may be disposed apart from each other.

In one embodiment of the present invention, the plurality of conductive patterns may include a first conductive pattern and a second conductive pattern, the first conductive pattern may include a first conductive stem extending in one direction and a plurality of first conductive branches extending in a direction intersecting the first conductive stem, the second conductive pattern may include a second conductive stem extending parallel to the first conductive stem and a plurality of second conductive branches extending in a direction intersecting the second conductive stem, and the first conductive branches and the second conductive branches may be disposed alternately with one another.

In one embodiment of the present invention, when the pressure is generated, the conductive layer and the circuit layer may come into contact, and the conductive layer may electrically connect the first conductive pattern and the second conductive pattern.

In one embodiment of the present invention, the pressure-sensitive stacking structure may further include a protective layer disposed on outer surfaces of the conductive layer and the circuit layer.

One aspect of the present invention provides a method of manufacturing a pressure-sensitive stacking structure, the method including: a circuit layer attaching step of attaching a circuit layer to a rotary drum; a separating layer forming step of forming a separating layer on a surface of the circuit layer; and a conductive layer forming step of forming a conductive layer that is pressure-sensitive on the separating layer, wherein the separating layer may be formed by performing one of a spin coating method, an electrospinning method, and a roll-to-roll method on at least one of polydimethylsiloxane (PDMS), thermoplastic polyurethane (TPU), and epoxy.

In one embodiment of the present invention, in the electrospinning method, the separating layer may be formed by, in a state in which a TPU or epoxy solution is injected into a spinning device in the form of an injector and an electric field is applied between the spinning device and the rotary drum, connecting a nozzle of the spinning device to a high-voltage power supply device, charging the solution by injecting a charge into the solution being discharged, and discharging the solution to the surface of the circuit layer.

In one embodiment of the present invention, the method may further include forming a protective layer on outer surfaces of the conductive layer and the circuit layer.

One aspect of the present invention provides a golf practice device including a shaft, a head portion provided at one side of the shaft, and a grip portion provided to surround an outer portion of the shaft at the other side of the shaft, the golf practice device including: a pressure-sensitive stacking structure provided between the shaft and the grip portion and configured to sense a pressure applied to the grip portion and generate pressure data, wherein the pressure-sensitive stacking structure includes a conductive layer that is pressure-sensitive, a circuit layer disposed to face the conductive layer and having a plurality of conductive patterns, and a separating layer disposed between the conductive layer and the circuit layer and formed of a fibrous tissue including a plurality of fibers, and, when a pressure is generated, the conductive layer and the circuit layer may come into contact, and the pressure may be detected.

In one embodiment of the present invention, the golf practice device may further include: a data processing module disposed in the shaft to process the pressure data; and a capsule structure having an inner space in which the data processing module is mounted and allowing the data processing module to be placed inside the shaft, wherein the capsule structure may allow the data processing module to be disposed at a position that overlaps the grip portion.

In one embodiment of the present invention, the capsule structure may include a body portion on which the data processing module is mounted and a flange portion provided at one side of the body portion, the flange portion may be exposed to the outside of the other side of the shaft, and a power terminal that receives power from the outside may be provided at the flange portion.

In one embodiment of the present invention, the body portion may include a first body having the inner space in which the data processing module is mounted and a second body coupled to the first body to cover the inner space.

In one embodiment of the present invention, the golf practice device may further include a swing data collector sensing a swing of a golfer to generate swing data.

### Advantageous Effects

A pressure-sensitive stacking structure for a sports training device according to the present invention can measure a pressure with which a golfer, who is a player, holds a grip of a golf club and derive pressure data, thereby assisting in golf practice. Accordingly, a golf practice device according to the present invention can correct a swing and a grip pressure of a golfer and induce an improvement in the golfer's golfing ability.

### DESCRIPTION OF DRAWINGS

FIG. 1 is a view for describing a golf practice device according to one embodiment of the present invention.

FIG. 2 is a partially-cut perspective view for describing an area that overlaps a grip portion illustrated in FIG. 1.

FIG. 3 is a cross-sectional view for describing the area overlapping the grip portion that is illustrated in FIG. 2.

FIG. 4 is a view for describing a pressure-sensitive stacking structure illustrated in FIG. 2.

FIG. 5 is a view for describing a circuit layer illustrated in FIG. 4.

FIG. 6 is a view for describing conductive patterns illustrated in FIG. 5.

FIG. 7 is a perspective view for describing a capsule structure and fixing members illustrated in FIG. 2.

FIG. 8 is an exploded perspective view for describing the capsule structure and the fixing members illustrated in FIG. 7.

FIG. 9 is a cross-section of the capsule structure illustrated in FIG. 7.

FIG. 10 is a plan view for describing a flange portion of the capsule structure illustrated in FIG. 7.

FIG. 11 is a view for describing the relationship of a data processing module, a data collection module, and an external device.

FIG. 12 is a view for describing the data collection module illustrated in FIG. 11.

FIG. 13 is a view for describing a method of manufacturing the pressure-sensitive stacking structure for a sports training device that is illustrated in FIGS. 1 to 12.

FIG. 14 is a view for describing a separating layer forming step illustrated in FIG. 13.

FIG. 15 is a cross-sectional image for describing a state in which a separating layer is formed on a circuit layer.

FIG. 16 is a top-view image for describing the state in which the separating layer is formed on the circuit layer.

FIGS. 17 and 18 are enlarged images for describing a fibrous tissue in the separating layer.

Note that the accompanying drawings are only exemplary and are provided as reference for understanding of the technical spirit of the present invention, and the scope of the present invention is not limited by the accompanying drawings.

### MODES OF THE INVENTION

General terms that are currently widely used have been selected as terms used in the present invention, but some terms may have been arbitrarily selected by the applicant in certain cases, and in such cases, the meanings of the terms should be understood in consideration of meanings described or used in details for carrying out the invention, instead of being simply defined based on the names of the terms.

Terms used in the present application are used to describe specific embodiments and are not intended to limit the present invention. A singular expression includes a plural expression unless the context clearly indicates otherwise. In the application, terms such as “include” or “have” should be understood as specifying that features, numbers, steps, operations, components, parts, or combinations thereof are present and not as precluding the possibility of the presence or addition of one or more other features, numbers, steps, operations, components, parts, or combinations thereof in advance.

The objectives, specific advantages, and novel features of the present invention should become more apparent from the following detailed description and exemplary embodiments. In addition, in describing the present invention, when detailed description of a related known art is determined as having the possibility of unnecessarily obscuring the gist of the present invention, the detailed description thereof will be omitted.

In addition, terms including ordinals such as “first” and “second” may be used to describe various components, but the components are not limited by the terms. The terms are only used for the purpose of distinguishing one component from another component.

A golf practice device according to one embodiment of the present invention will be described below with reference to the accompanying drawings.

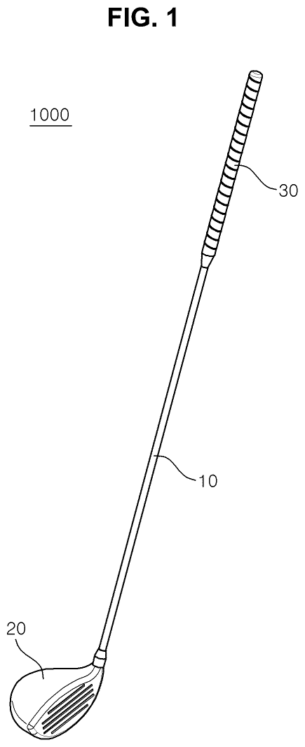

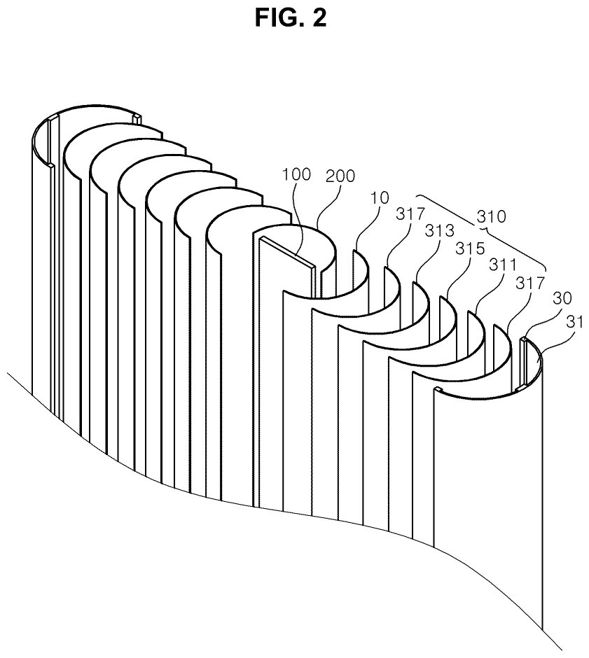

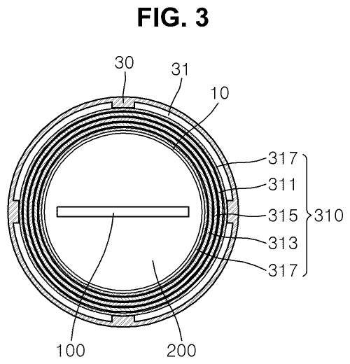

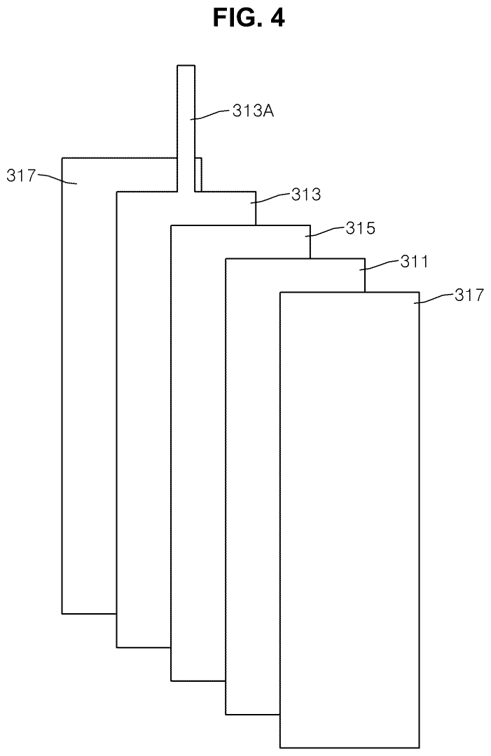

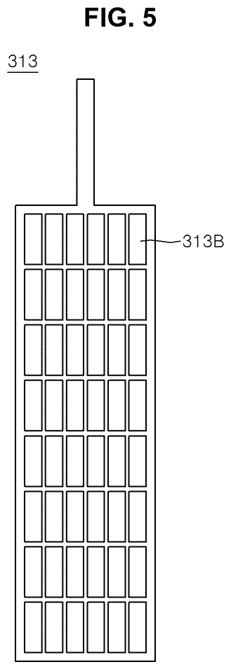

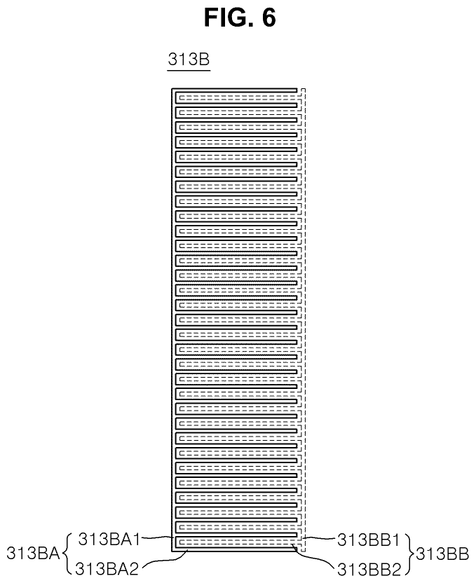

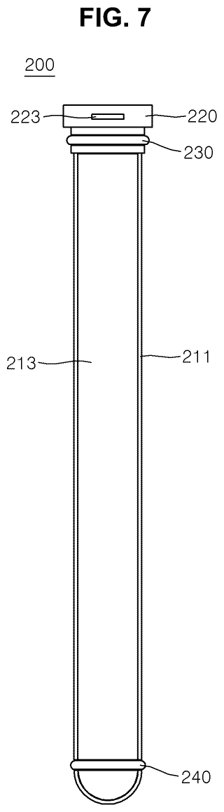

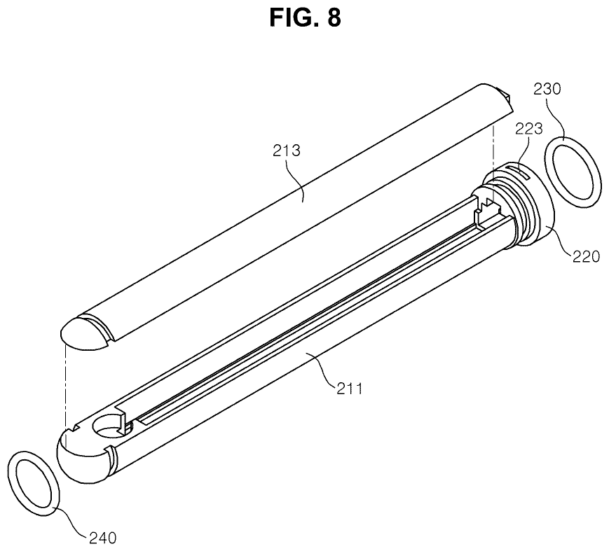

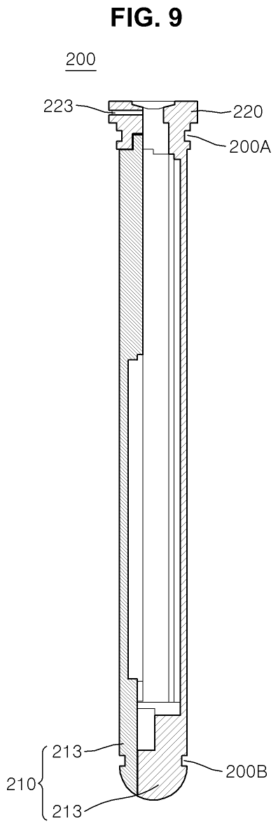

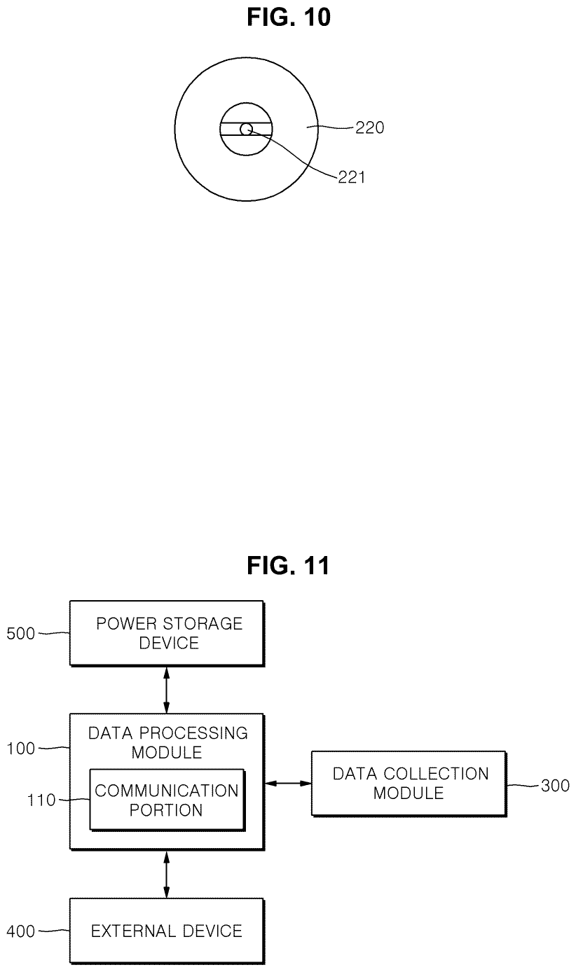

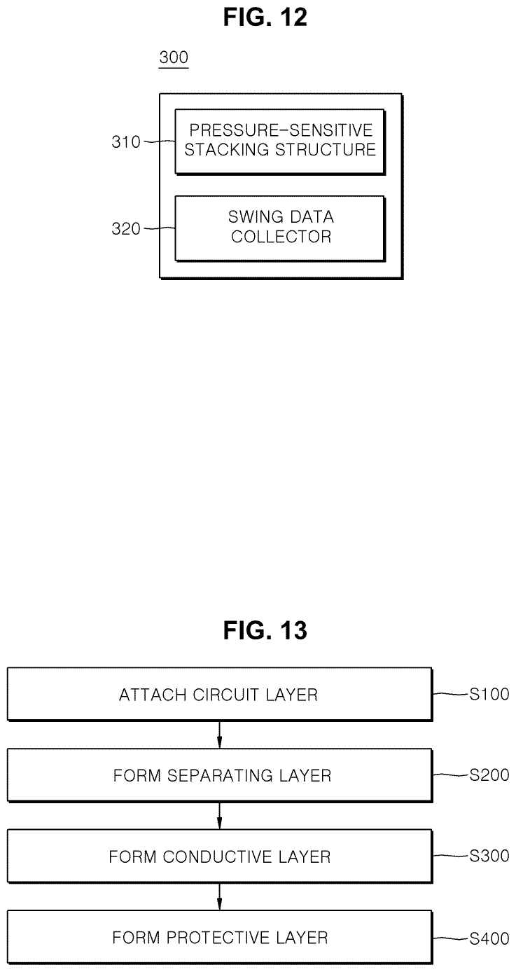

FIG. 1 is a view for describing a golf practice device according to one embodiment of the present invention. FIG. 2 is a partially-cut perspective view for describing an area that overlaps a grip portion illustrated in FIG. 1. FIG. 3 is a cross-sectional view for describing the area overlapping the grip portion that is illustrated in FIG. 2. FIG. 4 is a view for describing a pressure-sensitive stacking structure illustrated in FIG. 2. FIG. 5 is a view for describing a circuit layer illustrated in FIG. 4. FIG. 6 is a view for describing conductive patterns illustrated in FIG. 5. FIG. 7 is a perspective view for describing a capsule structure and fixing members illustrated in FIG. 2. FIG. 8 is an exploded perspective view for describing the capsule structure and the fixing members illustrated in FIG. 7. FIG. 9 is a cross-section of the capsule structure illustrated in FIG. 7. FIG. 10 is a plan view for describing a flange portion of the capsule structure illustrated in FIG. 7. FIG. 11 is a view for describing the relationship of a data processing module, a data collection module, and an external device. FIG. 12 is a view for describing the data collection module illustrated in FIG. 11.

Referring to FIGS. 1 to 12, a golf practice device 1000 according to one embodiment of the present invention may collect and process swing data related to a swing of a golfer, who is a user, and pressure data related to a pressure with which the golfer holds a golf club. In addition, the golf practice device 1000 may send the processed data to an external device. The external device may analyze the received data and may derive methods of correcting a swing trajectory of the golfer and a way in which the golfer grips a golf club.

The golf practice device 1000 described above may include a shaft 10, a head portion 20, and a grip portion 30.

The shaft 10 may have a shape that has a predetermined diameter and extends in one direction. The head portion 20 may be connected to one side of the shaft 10, and the grip portion 30 may be connected to the other side of the shaft 10.

The shaft 10 may have the shape of a tube or a pipe. In addition, the shaft 10 may have a form in which a diameter toward the head portion 20 is smaller than a diameter toward the grip portion 30. In addition, the shaft 10 may have a form in which the diameter toward the head portion 20 and the diameter toward the grip portion 30 are the same.

The head portion 20 may be connected to the one side of the shaft 10 and may hit a golf ball through a swing of a golfer. The head portion 20 may have a form that can accurately hit a golf ball through a swing of a golfer.

The grip portion 30 is provided at the other side of the shaft 10 and allows a golfer to grip the golf practice device. The grip portion 30 may be formed of various materials that can improve a grip feeling of the golfer. For example, the grip portion 30 may be formed of a natural rubber material.

In one embodiment of the present invention, a data processing module 100, a capsule structure 200, and a data collection module 300 may be provided in an area of the shaft 10 that is adjacent to the grip portion 30. That is, the golf practice device 1000 may further include the data processing module 100, the capsule structure 200, and the data collection module 300.

The data processing module 100 may be disposed inside the shaft 10. In particular, the data processing module 100 may be mounted in an inner space of the capsule structure 200 and may be, together with the capsule structure 200, disposed in an area of the shaft 10 that overlaps the grip portion 30.

The data processing module 100 may process various data for golf practice. For example, the data processing module 100 may process swing data related to a swing of a golfer and pressure data related to a pressure with which the golfer grips the grip portion that are collected by the data collection module 300 and may generate training data according to results of processing.

The data processing module 100 may transmit the generated training data to an external device 400. To this end, the data processing module 100 may include a communication portion 110 for transmitting the data to the external device 400. That is, the data processing module 100 may be connected to the external device 400 through a wireless network. Here, the wireless network may be a connection structure in which an information exchange is possible between different nodes such as the data processing module 100 and the external device 400. Examples of such a network may include a radiofrequency (RF) network, a 3rd Generation Partnership Project (3GPP) network, a Long Term Evolution (LTE) network, a 5th Generation Partnership Project (5GPP) network, a World Interoperability for Microwave Access (WIMAX) network, the Internet, a Local Area Network (LAN), a Wireless Local Area Network (WLAN), a Wide Area Network (WAN), a Personal Area Network (PAN), a Bluetooth network, a near-field communication (NFC) network, a satellite broadcasting network, an analog broadcasting network, a Digital Multimedia Broadcasting (DMB) network, and the like, but the network is not limited thereto.

In addition, although an example in which the data processing module 100 is connected to the external device 400 through a wireless network has been described in one embodiment of the present invention, the present invention is not limited thereto. For example, the data processing module 100 may be connected to the external device 400 through a wired network. In particular, the data processing module 100 may be connected to the external device 400 through a data connection device such as a wired cable.

The data processing module 100 may store the training data. To this end, the data processing module 100 may include a memory that can store data. The memory may store the swing data and the pressure data in addition to the training data.

Meanwhile, although an example in which the data processing module 100 transmits the training data generated by processing the swing data and the pressure data to the external device 400 has been described in one embodiment of the present invention, the present invention is not limited thereto. The data processing module 100 may transmit the swing data and the pressure data to the external device 400 through the communication portion 110 without processing the swing data and the pressure data. In this case, the external device 400 may process the swing data and the pressure data and may generate training data according to results of processing.

The capsule structure 200 may be disposed inside the shaft 10. In particular, the capsule structure 200 may be disposed in the area of the shaft 10 that overlaps the grip portion 30.

The capsule structure 200 may have an inner space in which the above-described data processing module 100 can be mounted. As the data processing module 100 is mounted in the inner space of the capsule structure 200, the data processing module 100 can be disposed in the area of the shaft 10 that overlaps the grip portion 30. In addition, as the data processing module 100 is mounted in the inner space of the capsule structure 200, a change in the position of the data processing module 100 due to a swing of a golfer can be prevented.

The capsule structure 200 may have a shape that extends in one direction, for example, a direction in which the shaft 10 extends. For example, the capsule structure 200 may have the shape of a rotating body that extends in one direction.

For the data processing module 100 to be accommodated in the inner space of the capsule structure 200, the capsule structure 200 may be formed to be longer than a length of the data processing module 100. However, in order to prevent a weight increase due to the capsule structure 200 and allow the capsule structure 200 to be disposed to overlap the grip portion 30, the capsule structure 200 may be formed to be shorter than a length of the grip portion 30.

The capsule structure 200 may include a body portion 210 and a flange portion 220.

The body portion 210 may provide the inner space in which the data processing module 100 is mounted. That is, the data processing module 100 may be mounted in the inner space of the body portion 210. The body portion 210 may include a first body 211 and a second body 213.

The first body 211 may have the inner space in which the data processing module 100 is mounted, and the data processing module 100 may be mounted in the inner space.

The second body 213 may be coupled to the first body 211 and may cover the inner space of the first body 211. Therefore, the second body 213 can prevent the data processing module 100 from being exposed to the outside or falling.

The flange portion 220 may be provided at one side of the body portion 210. In addition, the flange portion 220 may be exposed to the outside of the other side of the shaft 10.

A diameter of the flange portion 220 may be larger than a diameter of the body portion 210. In addition, the diameter of the flange portion 220 may be substantially the same as an outer diameter of the shaft 10. Therefore, since the diameter of the flange portion 220 and the outer diameter of the shaft 10 are the same, an exterior of the other side of the shaft 10 may have a smooth shape.

In addition, a power terminal 221 that receives power from the outside may be provided at the flange portion 220. For example, as illustrated in FIG. 10, the power terminal 221 may be provided on an end surface of the flange portion 220.

Meanwhile, although an example in which the power terminal 221 is provided at the flange portion 220 has been described in one embodiment of the present invention, the present invention is not limited thereto. A data terminal, in addition to the power terminal 221, may be further provided at the flange portion 220. Here, the data terminal may connect the data processing module 100 and the data collection module 300 or may connect the data processing module 100 and the external device 400 through a data cable.

In one embodiment of the present invention, at least a portion of an outer portion of the capsule structure 200 may be spaced from an inner circumference of the shaft 10.

To this end, a fixing member that can separate the outer portion of the capsule structure 200 and the inner portion of the shaft 10 may be provided on at least one of both sides of the capsule structure 200. For example, a first fixing member 230 may be provided on one side of the capsule structure 200, and a second fixing member 240 may be provided on the other side of the capsule structure 200.

The first fixing member 230 and the second fixing member 240 may allow the capsule structure 200 to be fixed to the inner portion of the shaft 10 in addition to separating the outer portion of the capsule structure 200 and the inner portion of the shaft 10. In particular, the first fixing member 230 and the second fixing member 240 may separate at least an area of the capsule structure 200 that is between the first fixing member 230 and the second fixing member 240 from the inner circumference of the shaft 10.

At least one of the first fixing member 230 and the second fixing member 240 may be made of an elastic material, for example, a material such as elastic rubber. In addition, at least one of the first fixing member 230 and the second fixing member 240 may have a shape that extends along an outer circumference of the capsule structure 200. That is, at least one of the first fixing member 230 and the second fixing member 240 may serve as an O-ring.

In addition, the capsule structure 200 may include coupling grooves that allow the first fixing member 230 and the second fixing member 240 to be coupled. For example, the capsule structure 200 may include a first coupling groove 200A coupled to the first fixing member 230 and a second coupling groove 200B coupled to the second fixing member 240. The first coupling groove 200A and the second coupling groove 200B may be provided along the outer circumference of the capsule structure 200.

In one embodiment of the present invention, the golf practice device 1000 may further include a power storage device 500. The power storage device 500 may store power supplied to the data processing module 100.

The power storage device 500 may be disposed at a position that overlaps the grip portion 30. For example, the power storage device 500 may be provided in a portion of the inner space of the capsule structure 200 that overlaps the grip portion 30.

The power storage device 500 described above may be provided as a secondary battery. Therefore, the power storage device 500 may store power supplied from the outside. For example, the power storage device 500 may be electrically connected to the power terminal 221 and may store the power coming from an external power source through the power terminal 221.

Meanwhile, although an example in which the power storage device 500 is provided as a secondary battery has been described above in one embodiment of the present invention, the present invention is not limited thereto. For example, the power storage device 500 may be provided as a replaceable primary battery. Therefore, when the power stored in the power storage device 500 is used up, the power storage device 500 in which the power is used up may be separated and removed from the golf practice device 1000. Then, a new power storage device 500 in which power is stored may be coupled to the golf practice device 1000.

The data collection module 300 may collect data related to at least one of a swing of a golfer and a grip pressure on the grip portion 30. For example, the data collection module 300 may collect at least one of swing data related to a swing of a golfer and pressure data related to a grip pressure applied on the grip portion 30 by the golfer.

To this end, the data collection module 300 may include at least one of a pressure-sensitive stacking structure 310 and a swing data collector 320. For example, the data collection module 300 may include only one of the pressure-sensitive stacking structure 310 and the swing data collector 320 or may include both the pressure-sensitive stacking structure 310 and the swing data collector 320.

The pressure-sensitive stacking structure 310 may generate pressure data in which a pressure applied to each point on the grip portion 30 by a golfer is transformed into numerical data and may transmit the pressure data to the data processing module 100.

The pressure-sensitive stacking structure 310 may be disposed to overlap the grip portion 30. For example, the pressure-sensitive stacking structure 310 may be disposed between the inner circumference of the grip portion 30 and the outer circumference of the shaft 10.

As illustrated in FIGS. 2 to 6, the pressure-sensitive stacking structure 310 may include a conductive layer 311, a circuit layer 313, and a separating layer 315. The conductive layer 311, the circuit layer 313, and the separating layer 315 of the pressure-sensitive stacking structure 310 may be disposed between the shaft 10 and the grip portion 30 and may be provided in a stacked form.

The conductive layer 311 is disposed between the shaft 10 and the grip portion 30 and is pressure-sensitive to allow the pressure-sensitive stacking structure 310 to detect the pressure generated on the grip portion 30.

The conductive layer 311 may be formed of a material that has resistance changing according to pressure and has resilience. For example, the conductive layer 311 may be formed of a pressure-sensitive nonwoven fabric. In addition, in a state in which a pressure is not applied, the conductive layer 311 may have a sheet resistance ranging from 180 Ω/sq to 220 Ω/sq, for example, a sheet resistance of 200 Ω/sq. When a pressure is applied to the conductive layer 311, the resistance of the conductive layer 311 may decrease.

The conductive layer 311 may have a thickness of 0.8 mm or less.

The conductive layer 311 may be provided between the circuit layer 313 and the grip portion 30. The resistance of an area of the conductive layer 311 where the pressure is generated may decrease. Therefore, the conductive layer 311 with a decreased resistance may allow only a specific position on the circuit layer 313 to be conductive so that a pressure sensing signal of the position where the pressure is applied is transmitted through the circuit layer 313.

The circuit layer 313 may be disposed to face the conductive layer 311. For example, the circuit layer 313 may be disposed between the shaft 10 and the conductive layer 311.

The circuit layer 313 may transmit the pressure generated on the conductive layer 311 to the data processing module 100. That is, the pressure-sensitive stacking structure 310 may generate pressure data by detecting a pressure generated on each point of the grip portion 30 and may transmit the generated pressure data to the data processing module 100.

In one embodiment of the present invention, the circuit layer 313 may be provided in the form of a flexible film that includes a plurality of pattern areas 313B having a plurality of conductive patterns. For example, the circuit layer 313 may be provided in the form of a flexible printed circuit board (FPCB). Here, the plurality of pattern areas 313B may be disposed apart from each other.

The conductive patterns included in the pattern areas 313B may include a first conductive pattern 313BA and a second conductive pattern 313BB.

The first conductive pattern 313BA may include a first conductive stem 313BA1 extending in one direction and a plurality of first conductive branches 313BA2 extending from the first conductive stem 313BA1 in a direction intersecting the first conductive stem 313BA1.

The second conductive pattern 313BB may include a second conductive stem 313BB1 extending in one direction and a plurality of second conductive branches 313BB2 extending from the second conductive stem 313BB1 in a direction intersecting the second conductive stem 313BB1. Here, the second conductive stem 313BB1 may extend in a direction substantially parallel to the first conductive stem 313BA1, and the second conductive branches 313BB2 may extend toward the first conductive stem 313BA1. In addition, the first conductive branches 313BA2 and the second conductive branches may be disposed alternately with one another.

When a pressure is applied to the pattern areas 313B, the first conductive pattern 313BA and the second conductive pattern 313BB may come into contact with the conductive layer 311 and may form a current path. Therefore, whether the pressure has been applied to the pattern areas 313B may be determined based on whether a current or voltage signal is transmitted from the pattern areas 313B to the data processing module 100.

An output terminal 313A that can send pressure data to the data processing module 100 may be provided at one side of the circuit layer 313. The output terminal 313A may have a shape that extends from one side of the circuit layer 313. The separating layer 315 may be disposed between the conductive layer 311 and the circuit layer 313. The separating layer 315 may have restorability and may separate the conductive layer 311 and the circuit layer 313. Due to the restorability of the separating layer 315, the pressure-sensitive stacking structure 310 is capable of accurate pressure sensing in relation to local pressure.

The separating layer 315 may have a thickness ranging from 0.01 mm to 0.02 mm. Although a thinner separating layer 315 is preferable because the thinner the thickness of the separating layer 315, the smaller the influence on the thickness of the grip portion 30 in design, the separating layer 315 may preferably have a thickness in the above range in consideration of the restorability described above.

The separating layer 315 may have heat resistance and may be formed of a fibrous tissue including a plurality of fibers. For example, the separating layer 315 may have the form of a fibrous membrane woven using a plurality of fibers.

The separating layer 315 may have a high pressure sensing range of up to 10 Kg/cm² or lower. This allows the pressure transmitted through the grip portion to be accurately measured for each pressing portion. A discrete sensing result can be provided for each pressing portion.

In addition, the separating layer 315 may have heat resistance up to a temperature of 150° C. or higher. This allows flexibility to be secured in the manufacturing process and enables a more advantageous process, for example, a process such as an electrospinning method, to be applied.

The separating layer 315 may be formed using at least one selected from the group consisting of polydimethylsiloxane (PDMS), thermoplastic polyurethane (TPU), and epoxy.

In addition, the separating layer 315 may be formed by performing one of a spin coating method, an electrospinning method, and a roll-to-roll method on the at least one selected from the group. For example, the separating layer 315 may have the form of a fibrous membrane formed by electrospinning TPU or epoxy.

When a pressure is applied to the grip portion 30, the conductive layer 311 may be deformed and the separating layer 315 may be compressed due to the pressure. When the conductive layer 311 is deformed and the separating layer 315 is compressed due to the pressure, the conductive layer 311 may come into contact with the first conductive pattern 313BA and the second conductive pattern 313BB of the pattern areas 313B through inter-fiber spaces of the separating layer 315. In addition, due to the pressure, resistance may decrease in the area of the conductive layer 311 to which the pressure is applied. Therefore, the first conductive pattern 313BA and the second conductive pattern 313BB may be electrically connected, and current may flow therein. Here, the current flowing in the first conductive pattern 313BA and the second conductive pattern 313BB may be transmitted to the data processing module 100.

Here, the current or voltage transmitted from the pressure-sensitive stacking structure 310 to the data processing module 100 may change due to the resistance decreased due to the pressure, and the changed current or voltage may be transmitted in the form of pressure data to the data processing module 100.

In one embodiment of the present invention, the pressure-sensitive stacking structure 310 may further include a protective layer 317. The protective layer 317 may be provided between the conductive layer 311 and the grip portion 30 and between the circuit layer 313 and the shaft 10. That is, the protective layer 317 is a layer exposed to the outside of the pressure-sensitive stacking structure 310 and is able to protect the conductive layer 311 and the circuit layer 313 therein.

The protective layer 317 may have a thickness ranging from 0.04 mm to 0.06 mm, for example, a thickness of 0.05 mm. The protective layer 317 may be made of a material that can be heat-coated. Meanwhile, although an example in which the protective layer 317 is made of a material that can be heat-coated has been described in one embodiment of the present invention, the present invention is not limited thereto. For example, the protective layer 317 may be made of an adhesive film.

Meanwhile, although not illustrated in the drawings, an adhesive layer may be provided between the protective layer 317 adhered to the circuit layer 313 and the shaft 10 and between the protective layer 317 adhered to the conductive layer 311 and the grip portion 30. The adhesive layer may adhere the pressure-sensitive stacking structure 310 and the shaft 10 and may adhere the pressure-sensitive stacking structure 310 and the grip portion 30. Here, the adhesive layer may be formed of an adhesive or a double-sided tape.

In one embodiment of the present invention, since the pressure-sensitive stacking structure 310 is provided on the outer circumference of the shaft 10, an insertion portion 223 into which the output terminal 313A is able to be inserted may be provided in a portion of the capsule structure 200. For example, the insertion portion 223 may be provided in the flange portion 220. The insertion portion 223 is a type of through-hole and may connect the inner space of the capsule structure 200 and an outer space of the capsule structure 200. Therefore, by being inserted into the insertion portion 223, the output terminal 313A may be electrically and/or physically connected to the data processing module 100.

The swing data collector 320 may sense a swing of a golfer to generate swing data and may transmit the swing data to the data processing module 100. The swing data collector 320 may be provided inside the shaft 10.

In one embodiment of the present invention, the swing data collector 320 may include a sensor, such as a gyro sensor, that can detect a movement trajectory, a movement speed, an acceleration, and the like of an object.

Meanwhile, the overall weight of the golf practice device 1000 may increase due to the capsule structure 200 and the data processing module 100. In particular, a weight of an area of the golf practice device 1000 that corresponds to the grip portion 30 may increase, and the center of mass of the golf practice device 1000 may change as a result. A golfer is very sensitive to an increase in the weight of the golf practice device 1000 and a change in the center of mass thereof. Therefore, it is necessary to prevent an unintentional increase in the weight of the golf practice device 1000 and change in the center of mass thereof.

Accordingly, the grip portion 30 according to one embodiment of the present invention may have a recessed portion 31 provided in a surface facing the shaft 10 as illustrated in FIG. 3. When the grip portion 30 has the recessed portion 31, the weight of the grip portion 30 may decrease. When the weight of the grip portion 30 decreases, the weight increase due to the capsule structure 200 and the data processing module 100 and the center-of-mass change can be prevented. That is, the recessed portion 31 of the grip portion 30 may offset the weight increased due to the capsule structure 200 and the data processing module 100. Through such a weight offset mechanism, the weight of the area corresponding to the grip portion 30 may be maintained consistent before and after mounting of the capsule structure 200 and the data processing module 100 according to one embodiment of the present invention.

Although the recessed portion 31, which is one embodiment of the weight offset mechanism, has been shown in a somewhat exaggerated scale in the drawings for the sake of convenience of description, the present invention is not limited to the illustrated example, and the recessed portion may have various other structures for offsetting the weight. For example, the weight offset mechanism may be realized with a recessed embossing shape (here, the recessed embossing shape may be formed irregularly or regularly).

In addition, according to another embodiment, the weight offset mechanism may be applied using a method of adjusting the density of the grip instead of using the above-described recessed portion 31. For example, the weight offset mechanism may be applied using a method of designing the density to be lower than the density required for the grip portion itself (referred to as “standard density”). Here, the design of the density lower than the standard density may be reflected through foaming or the like in a process of manufacturing the grip portion or may be reflected through using another material with a relatively low density. Either way, it is the same that it may be considered as the weight offset mechanism for preventing an unintentional increase in the weight and change in the center of mass when adopting the capsule structure 200 and the data processing module 100 to the golf practice device 1000.

Meanwhile, referring to FIGS. 11 and 12, the data processing module 100 and the data collection module 300 may operate using the power stored in the power storage device 500. In particular, the pressure-sensitive stacking structure 310 of the data collection module 300 may operate using the power stored in the power storage device 500.

For example, the first conductive pattern 313BA in the circuit layer 313 of the pressure-sensitive stacking structure 310 may be electrically connected to the power storage device 500, and the second conductive pattern 313BB may be electrically connected to the output terminal 313A. Therefore, when a pressure is applied to the grip portion 30, as the resistance of the conductive layer 311 decreases, the conductive layer 311 may electrically connect the first conductive pattern 313BA and the second conductive pattern 313BB. When the first conductive pattern 313BA and the second conductive pattern 313BB are electrically connected, as current is supplied to the output terminal 313A, a voltage changed due to the resistance of the conductive layer 311 may be transmitted, and the data processing module 100 may receive the voltage changed due to the resistance of the conductive layer 311 as pressure data.

In addition, the data processing module 100 may process the pressure data and the swing data collected by the pressure-sensitive stacking structure 310 and the swing data collector 320 of the data collection module 300 and may generate training data.

When the training data is generated, the data processing module 100 may send the training data to the external device 400.

The external device 400 may provide the training data related to the pressure of gripping the grip portion 30 and the swing trajectory to the golfer. The golfer may check the training data and may check corrections that should be made to his or her swing, and in this way, an improvement in golfing ability can be promoted.

As described above, the pressure-sensitive stacking structure 310 according to one embodiment of the present invention may include the separating layer 315 having heat resistance and formed of a fibrous tissue and the conductive layer 311 formed of a nonwoven fabric and having resilience.

Therefore, a manufacturing process performed at a high temperature, for example, a high temperature of 150° C., can be applied to the pressure-sensitive stacking structure 310. This allows flexibility to be secured in the manufacturing process and enables a more advantageous manufacturing process to be applied. In addition, the pressure-sensitive stacking structure 310 may have a high pressure sensing range. For example, the pressure-sensitive stacking structure 310 may have a high pressure sensing range of up to 10 Kg/cm² or lower. Therefore, the pressure-sensitive stacking structure 310 can accurately sense the pressure that sensitively changes locally. In this way, the pressure transmitted through the grip portion 30 can be accurately measured for each pressing portion.

On the other hand, in an existing pressure sensor having a decompression film such as Velostat and a circuit board, the decompression film is usually vulnerable to high temperatures. In particular, since deformation or a change in a physical property occurs in the decompression film at 70° C. or higher, it is difficult to apply a process performed at 70° C. or higher. Alternatively, even if the pressure sensor is manufactured, performance degradation may occur in the pressure sensor. In addition, since the pressure sensor having the decompression film such as Velostat and the circuit board only has a low pressure sensing range of 0.5 Kg/cm² or lower, it is difficult to obtain a discrete sensing result for each pressing portion.

The golf practice device 1000 including the pressure-sensitive stacking structure 310 described above can detect at least one of the swing data and pressure data of a golfer, for example, both the swing data and pressure data of the golfer and can generate training data by processing the swing data and pressure data, thereby assisting in correcting the golfer's technique of gripping the grip portion 30 and swing motion.

A method of manufacturing the pressure-sensitive stacking structure for a sports training device will be described below with reference to FIGS. 13 to 18.

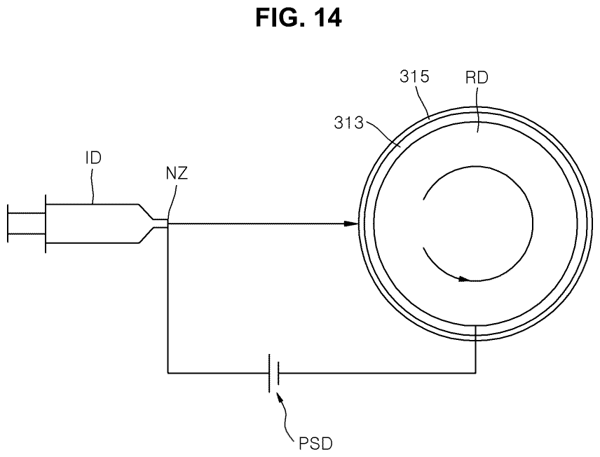

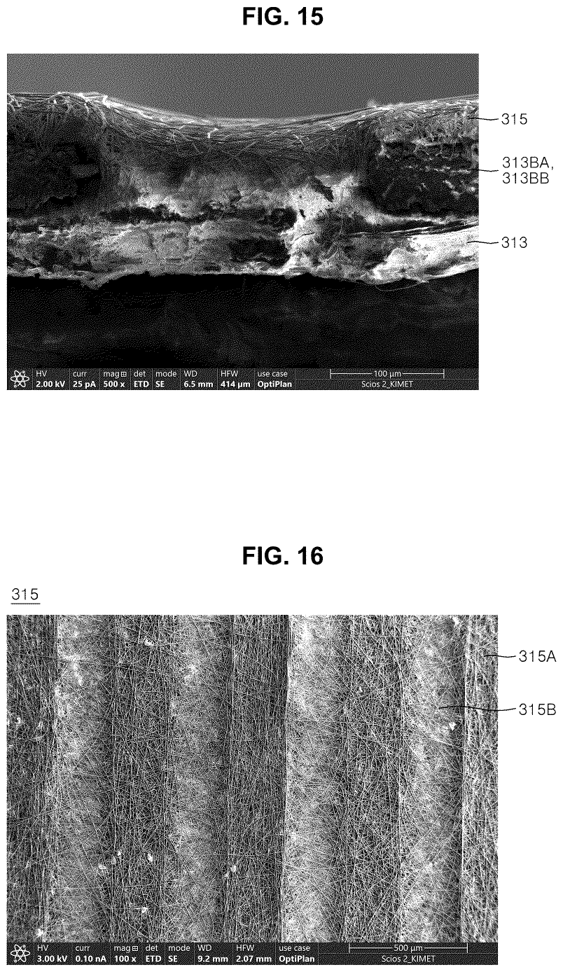

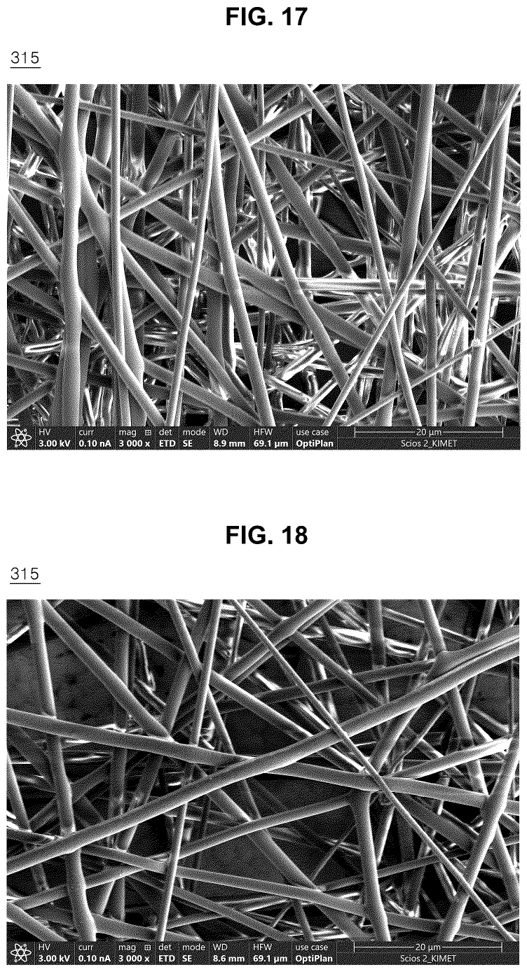

FIG. 13 is a view for describing a method of manufacturing the pressure-sensitive stacking structure for a sports training device that is illustrated in FIGS. 1 to 12. FIG. 14 is a view for describing a separating layer forming step illustrated in FIG. 13. FIG. 15 is a cross-sectional image for describing a state in which a separating layer is formed on a circuit layer. FIG. 16 is a top-view image for describing the state in which the separating layer is formed on the circuit layer. FIGS. 17 and 18 are enlarged images for describing a fibrous tissue in the separating layer.

Referring to FIGS. 13 to 18, the method of manufacturing the pressure-sensitive stacking structure for a sports training device may include a circuit layer attaching step (S100), a separating layer forming step (S200), a conductive layer forming step (S300), and a protective layer forming step (S400).

In the circuit layer attaching step (S100), a circuit layer 313 may be attached to a surface of a rotary drum RD. The circuit layer 313 may be provided in the form of a flexible film that includes a plurality of pattern areas 313B having a plurality of conductive patterns.

The conductive patterns included in the pattern areas 313B may include a first conductive pattern 313BA and a second conductive pattern 313BB.

The first conductive pattern 313BA may include a first conductive stem 313BA1 extending in one direction and a plurality of first conductive branches 313BA2 extending from the first conductive stem 313BA1 in a direction intersecting the first conductive stem 313BA1.

The second conductive pattern 313BB may include a second conductive stem 313BB1 extending in one direction and a plurality of second conductive branches 313BB2 extending from the second conductive stem 313BB1 in a direction intersecting the second conductive stem 313BB1. Here, the second conductive stem 313BB1 may extend in a direction substantially parallel to the first conductive stem 313BA1, and the second conductive branches 313BB2 may extend toward the first conductive stem 313BA1. In addition, the first conductive branches 313BA2 and the second conductive branches may be disposed alternately with one another.

When the circuit layer 313 is attached to the rotary drum RD, the separating layer forming step (S200) may be performed.

In the separating layer forming step (S200), a separating layer 315 may be formed on a surface of the circuit layer 313.

Here, the separating layer 315 may be formed by performing one of a spin coating method, an electrospinning method, and a roll-to-roll method on at least one of polydimethylsiloxane (PDMS), thermoplastic polyurethane (TPU), and epoxy. For example, the separating layer 315 may have the form of a fibrous membrane formed by electrospinning TPU or epoxy.

Forming the separating layer 315 using the electrospinning method will be described in more detail below.

First, a TPU or epoxy solution is injected into a spinning device ID in the form of an injector.

The solution injected into the spinning device ID may be spun toward the circuit layer 313 attached to the rotary drum RD through a nozzle NZ of the spinning device ID.

The nozzle NZ of the spinning device ID and the rotary drum RD may be connected to a high-voltage power supply device PSD. The nozzle NZ of the spinning device ID that is connected to the high-voltage power supply device PSD may charge the solution by injecting a charge into the solution being discharged.

In addition, an electric field may be applied to an area between the nozzle NZ of the spinning device ID and the rotary drum RD.

When the discharged solution is charged through the nozzle NZ of the spinning device ID, and the electric field is applied to the area between the nozzle NZ of the spinning device ID and the rotary drum RD as mentioned above, continuous fibers each having a fine diameter are seated on the circuit layer 313, and accordingly, the separating layer 315 may be formed. Here, the diameter of each fiber may range from several tens of nm to several hundreds of nm.

After the separating layer 315 is formed, a stacking structure in which the separating layer 315 is formed on the circuit layer 313 may be separated from the rotary drum RD.

Then, the conductive layer forming step (S300) may be performed.

In the conductive layer forming step (S300), a conductive layer 311 may be formed on the separating layer 315. The conductive layer 311 may be provided in a form that is attached onto the separating layer 315.

The conductive layer 311 may be formed of a material that has resistance changing according to pressure and has resilience. For example, the conductive layer 311 may be formed of a pressure-sensitive nonwoven fabric whose resistance decreases in an area where pressure is generated.

After the conductive layer 311 is formed, the protective layer forming step (S400) may be performed.

In the protective layer forming step (S400), a protective layer 317 may be formed on a lower surface of the circuit layer 313 and an upper surface of the conductive layer 311 to manufacture a pressure-sensitive stacking structure 310. Here, the lower surface of the circuit layer 313 and the upper surface of the conductive layer 311 may be an outer surface of the circuit layer 313 and an outer surface of the conductive layer 311. That is, the protective layer 317 is a layer exposed to the outside of the pressure-sensitive stacking structure 310 and is able to protect the conductive layer 311 and the circuit layer 313 therein.

Meanwhile, referring to FIGS. 15 and 16, it can be seen that the separating layer 315 formed on the circuit layer 313 is formed with a uniform thickness along the surface of the circuit layer 313. That is, due to concave and convex portions formed by the first conductive pattern 313BA and the second conductive pattern 313BB of the circuit layer 313, the separating layer 315 may also have concave and convex portions. Therefore, as illustrated in FIG. 16, the separating layer 315 may be divided into a first area 315A on the first conductive pattern 313BA and the second conductive pattern 313BB and a second area 315B between the first conductive pattern 313BA and the second conductive pattern 313BB.

In addition, referring to FIGS. 17 and 18, it can be seen that the separating layer 315 constitutes the form of a fibrous membrane woven using electrospun fibers. In particular, a plurality of inter-fiber spaces may be present between the fibers spun by electrospinning. Therefore, when a pressure is applied, the separating layer 315 is compressed, and accordingly, the conductive layer 311 may come into contact with the first conductive pattern 313BA and the second conductive pattern 313BB of the pattern areas 313B through the inter-fiber spaces of the separating layer 315.

The embodiments according to the present invention described above may be implemented in the form of program instructions that can be executed through various computer components to be recorded on a computer-readable recording medium. The computer-readable recording medium may include program instructions, data files, data structures, etc. alone or in combination. The program instructions recorded on the computer-readable recording medium may be specially designed and configured for the present invention, or may be known and available to those skilled in the art of computer software. Examples of the computer-readable recording medium include a hard disk, a floppy disk, a magnetic medium such as a magnetic tape, an optical recording medium such as CD-ROM and DVD, a magneto-optical medium such as a floptical disk, and hardware devices specially configured to store and execute program instructions, such as ROM, RAM, and flash memory. Examples of the program instructions include not only machine language codes generated by a compiler, but also high-level language codes that can be executed by a computer using an interpreter or the like. The hardware device may be modified to one or more software modules to perform processing according to the present invention, and vice versa.

The present invention is not limited to the embodiments described above, and of course, may include new embodiments in which at least two or more of the above embodiments are combined or at least one of the above embodiments and a known art are combined.

Although the present invention has been described in detail above using specific embodiments thereof, the embodiments are only for describing the present invention in detail, the present invention is not limited thereto, and it is apparent that modifications or improvements may be made by those of ordinary skill in the art within the technical spirit of the present invention.

Simple modifications or changes to the present invention all belong to the scope of the present invention, and a specific scope of protection of the present invention will become clear from the appended claims.

1-12. (canceled)

13. A method of manufacturing a pressure-sensitive stacking structure, the method comprising:
a circuit layer attaching step of attaching a circuit layer to a rotary drum;
a separating layer forming step of forming a separating layer on a surface of the circuit layer; and
a conductive layer forming step of forming a conductive layer that is pressure-sensitive on the separating layer,
wherein the separating layer is formed by performing one of a spin coating method, an electrospinning method, and a roll-to-roll method on at least one of polydimethylsiloxane (PDMS), thermoplastic polyurethane (TPU), and epoxy.

14. The method of claim 13, wherein, in the electrospinning method, the separating layer is formed by, in a state in which a TPU or epoxy solution is injected into a spinning device in the form of an injector and an electric field is applied between the spinning device and the rotary drum, connecting a nozzle of the spinning device to a high-voltage power supply device, charging the solution by injecting a charge into the solution being discharged, and discharging the solution to the surface of the circuit layer.

15. The method of claim 14, further comprising forming a protective layer on outer surfaces of the conductive layer and the circuit layer.

16-20. (canceled)
